(19) United States
(12) Patent Application Publication
(10) Pub. No.: US 2025/0379570 A1
(43) Pub. Date: Dec. 11, 2025

(54) CONSTANT DELAY DUTY-CYCLE CORRECTOR CIRCUIT AND METHOD FOR OPERATING THE SAME

(71) Applicant: TAIWAN SEMICONDUCTOR MANUFACTURING COMPANY LTD., HSINCHU (TW)

(72) Inventor: CHANG-YI LI, YUNLIN COUNTY (TW)

(21) Appl. No.: 18/736,602

(22) Filed: Jun. 7, 2024

(51) Int. Cl. H03K 5/156; H03K 5/133; H03K 5/135; H03K 19/21

(52) U.S. Cl. CPC H03K 5/1565; H03K 5/133; H03K 5/135; H03K 19/21

(57) ABSTRACT

The present disclosure provides an integrated circuit, which includes a divider stage, a frequency trimming stage, a voltage control stage, and a logic stage. The divider stage is configured to generate a first clock signal by dividing a frequency of an input clock signal. The frequency trimming stage is configured to add a first delay to the first clock signal to generate a second clock signal. The voltage control stage is configured to repeatedly adjust a second delay of the second clock signal according to a control signal generated by a feedback path to generate a third clock signal. The logic stage is configured to perform a logic operation according to the first clock signal and the third clock signal to generate an output clock signal.

### BACKGROUND

The number of high-speed circuits and high-speed systems continues to increase. Generally, the duty cycle of a clock signal in a high-speed circuit should be at 50%. However, due to variations in process, voltage, and temperature (PVT), the duty cycle of the clock signal is usually above or below 50%. In some cases, existing duty-cycle correctors can introduce timing synchronization issues due to rising edge variations in the output clock signal. Furthermore, while these correctors may be able to adjust the duty cycle to 50%, they may not effectively address differences in rising edge delay when the input clock signal exhibits varying duty cycle variations. This is particularly important in serializer/deserializer (Serdes) systems, where precise clock phase is needed for timing synchronization.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a high-speed circuit in accordance with some embodiments of the present disclosure.

FIG. 2 is a high-level block diagram of a duty-cycle corrector circuit in accordance with some embodiments of the present disclosure.

FIG. 3 is a block diagram of a duty-cycle corrector circuit in accordance with some embodiments of the present disclosure.

FIG. 4A is a waveform diagram of various clock signals within the duty-cycle corrector circuit 100A in FIG. 3.

FIG. 4B is a waveform diagram of input and output signals of the operational amplifier in FIG. 3.

FIG. 5 is a block diagram of a frequency multiplier circuit in accordance with some embodiments of the present disclosure.

FIG. 6 is a block diagram of a duty-cycle corrector circuit in accordance with some embodiments of the present disclosure.

FIG. 7 is a block diagram of a duty-cycle corrector circuit in accordance with some embodiments of the present disclosure.

FIG. 8 is a block diagram of a duty-cycle corrector circuit in accordance with some embodiments of the present disclosure.

FIG. 9A is a block diagram of a duty-cycle corrector circuit in accordance with some embodiments of the present disclosure.

FIG. 9B is a schematic diagram of the logic gate in FIG. 9A.

FIG. 10 is a block diagram of a frequency multiplier circuit in accordance with some embodiments of the present disclosure.

FIG. 11 is a block diagram of a duty-cycle corrector circuit in accordance with some embodiments of the present disclosure.

FIG. 12 is a block diagram of a duty-cycle corrector circuit in accordance with some embodiments of the present disclosure.

FIG. 13 is a flowchart of a method for operating a duty-cycle corrector circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In some embodiments, a clock duty-cycle corrector includes a divider stage, a frequency trimming stage, a voltage control stage, and a logic stage. The divider stage divides a frequency of an input clock signal to generate a first clock signal. A first delay is added to the first clock signal to generate a second clock signal via the frequency trimming stage, while a second delay is added to the second clock signal to generate a third clock signal via the voltage control stage, which is controlled by a voltage control signal generated by the. The logic stage performs a logic operation according to the first clocks signal and the third clock signal to generate an output clock signal, which has a duty cycle substantially equal to 50%.

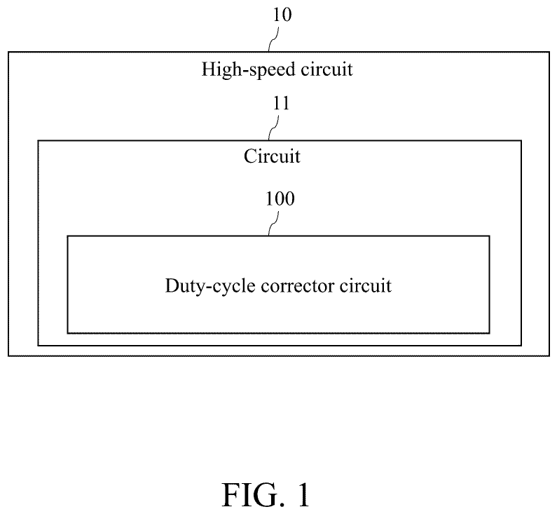

FIG. 1 is a block diagram of a high-speed circuit in accordance with some embodiments of the present disclosure. The high-speed circuit 10 can be any suitable type of a high-speed circuit, including a processing device, a memory input/output interface, and a high-frequency data converter. Example processing devices include, but are not limited to, a central processing unit, a microprocessor, and a digital signal processor. The high-speed circuit 10 typically includes multiple circuits, including a duty-cycle corrector circuit 100. In a non-limiting nonexclusive example, the duty-cycle corrector circuit 100 is implemented in a circuit 11. The circuit 11 can be any suitable circuit. Example circuits include, but are not limited to, a de-skew circuit, a memory input/output interface, a data transmission interface, and/or a data converter circuit.

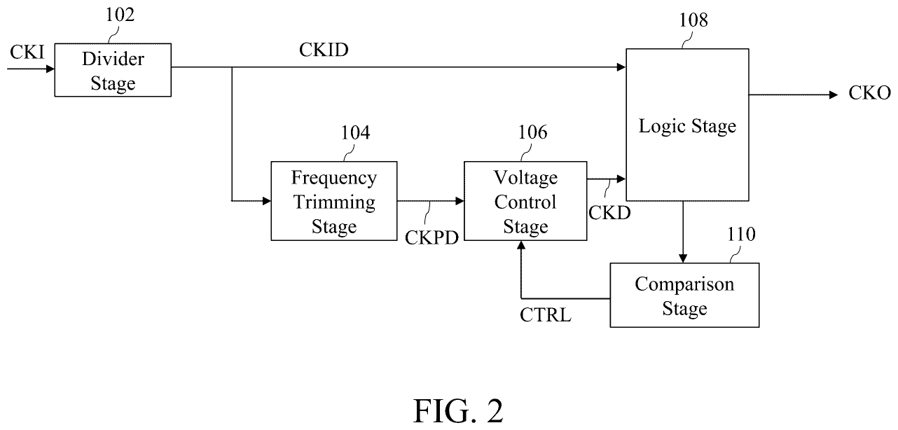

FIG. 2 is a high-level block diagram of a duty-cycle corrector circuit in accordance with some embodiments of the present disclosure. In some embodiments, the duty-cycle corrector circuit 100 may be configured to adjust the duty cycle of an input clock signal CKI to generate an output clock signal CKO with substantially 50% duty cycle. As depicted in FIG. 2, the duty-cycle corrector circuit 100 includes a divider stage 102, a frequency trimming stage 104, a voltage control stage 106, a logic stage 108, and a comparison stage 110. The divider stage 102 may be configured to divide the frequency of the input clock signal by a clock factor, such as 2, to generate a clock signal CKID (e.g., CKI/2). The clock signal CKID is fed to the frequency trimming stage 104 which is capable of adjusting the delay and/or frequency of the clock signal CKID to generate a clock signal CKPD. The clock signal CKPD is fed to the voltage control stage 106 which is capable of adjusting the delay of the clock signal CKID via a control signal CTRL to generate a clock signal CKD. In some embodiments, the control signal CTRL may be a voltage control signal Vctrl or a trimming code TC for the analog approach and digital approach, and the details thereof will be described later.

In some embodiments, the logic stage 108 may be configured to perform a logic operation, such as exclusive-OR (XOR) or exclusive-NOR (XNOR), according to the clock signals CKID and CKD to generate the output clock signal CKO. The comparison stage may be configured to compare the duty cycles between two delayed signals FB and FBB to generate the control signal CTRL to control the voltage used by the voltage control stage 106, thereby adjusting the delay of the clock signal CKD. In some embodiments, there may be single-to-differential (S2D) circuits for the clock signals CKID and CKD before the logic stage 108, allowing the logic stage 108 to perform the corresponding logic operation using aligned differential signals to improve the quality of the output clock signal CKO. More details about various stages 102 to 110 within the duty-cycle corrector circuit 100 will be described later.

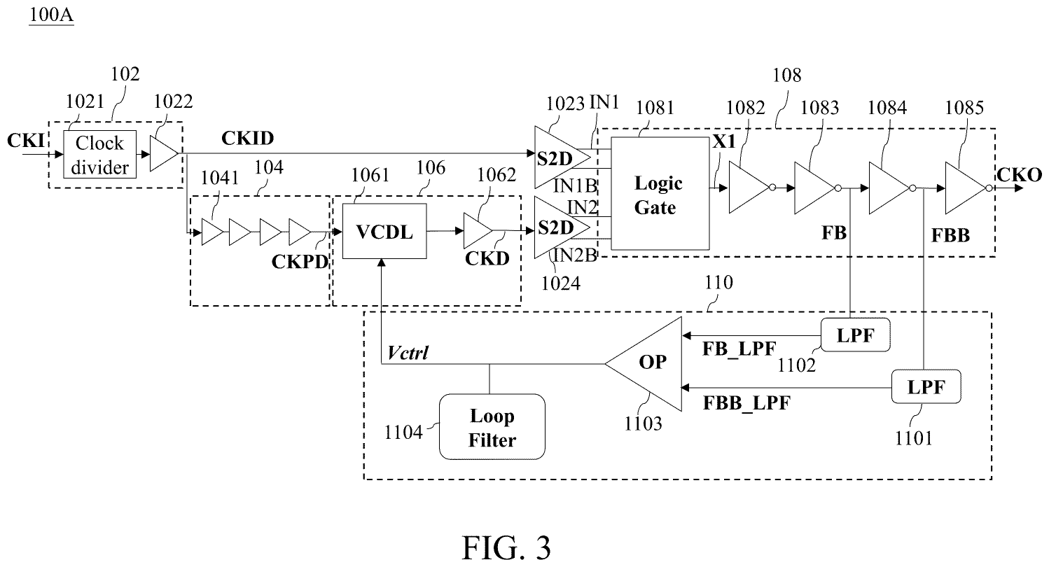

FIG. 3 is a block diagram of a duty-cycle corrector circuit in accordance with some embodiments of the present disclosure.

In some embodiments, the duty-cycle corrector circuit 100A includes a divider stage 102, a frequency trimming stage 104, a voltage control stage 106, a logic stage 108, and a comparison stage 110. The divider stage 102 includes a clock divider 1021 and a buffer 1022. The clock divider 1021 may be configured to divide the frequency of the input clock signal CKI by 2 to generate the clock signal CKID (e.g., CKI/2), which is buffered by the buffer 1022. In some embodiments, the clock divider 1021 can be implemented using a D flip-flop (not shown).

In some embodiments, the frequency trimming stage 104 may include one or more buffers 1041, with each buffer 1041 being implemented using two inverters connected in series. In other words, the frequency trimming stage 104 may be implemented using an inverter chain with an even number of inverters connected in series. Additionally, the delay caused by the frequency trimming stage 104 may be determined based on the value stored in the associated register (not shown) for frequency trimming.

In some embodiments, the voltage control stage 106 may include a voltage controlled delay line (VCDL) 1061 and a buffer 1062. The VCDL 1061 may be implemented using one or more current-starved delay lines (not shown), but the present disclosure is not limited thereto. For example, the delay of the clock signal CKD, which is buffered by the buffer 1062, generated by the VCDL 1061 can be adjusted by the voltage applied to the VCDL 1061 which is controlled the control signal Vctrl generated by the comparison stage 110. Additionally, the delay of the clock signal CKD can be either a positive value or a negative value.

In some embodiments, the logic stage 108 may include a logic gate 1081 and a plurality of inverters 1082 to 1085. The logic gate 1081 can be an XOR gate or an XNOR gate that is implemented using CMOS (complementary metal oxide semiconductor) circuits. The clock signal generated by the logic gate 1081 passes through the inverter chain, which includes the inverters 1082 to 1085 to obtain the output clock signal CKO. Additionally, the signals FB and FBB generated by the inverters 1083 and 1084 are provided to the low pass filters (LPF) 1102 and 1101, respectively, allowing the operational amplifier 1103 to compare the filtered signals FB_LPF and FBB_LPF. In some embodiments, the filtered signals FB_LPF and FBB_LPF generated by LPFs 1102 and 1101 may be transmitted to the positive input terminal and negative input terminal of the operational amplifier 1103, respectively. Alternatively, the filtered signals FB_LPF and FBB_LPF generated by LPFs 1102 and 1101 may be transmitted to the negative input terminal and positive input terminal of the operational amplifier 1103, respectively.

Specifically, the S2D circuit 1023 may be configured to generate differential clock signals IN1 and IN1B associated with the clock signal CKID, while the S2D circuit 1024 may be configured to generate differential clock signals IN2 and IN2B associated with the clock signal CKD. For example, the differential clock signals IN1 and IN1B may be in-phase and out-phase clock signals for the clock signal CKID, while the differential clock signals IN2 and IN2B may be in-phase and out-phase clock signals for the clock signal CKD. Additionally, the clock signal IN1 may substantially align with the clock signal IN1B, while the clock signal IN2 may be substantially align with the clock signal IN2B. For purposes of description, the logic gate 1081 is implemented using a two-input XOR gate in the following embodiments. It should be noted that the output signal X1 of the logic gate 1081 can be expressed as: X1=(IN1·IN2B)+(IN2·IN1B). When the signals IN1B and IN2B are not available (e.g., omitting the S2D circuits 1023 and 1024), it indicates that the logic gate 1081 should include two inverters to convert the signals IN1 and IN2 into the signals IN1B and IN2B, respectively.

In some embodiments, the differential clock signal pairs IN1/IN1B and IN2/IN2B substantially align with each other, and it indicates that the logic gate 1081 can receive the differential clock signals IN1/IN1B substantially at the same time, and receive IN2/IN2B substantially at the same time, thereby improving the timing accuracy of the output signal X1 generated by the logic gate 1081. For example, when the clock signal IN1 differs from the clock signal IN2 (i.e., IN1=0 and IN2=1, or IN1=1 and IN2=0), the signal X1 generated by the logic gate 1081 is in the high logic state (e.g., “1”). When the clock signals IN1 and IN2 have the same logic state (e.g., both “1” or “0”), the signal X1 generated by the XOR gate is in the low logic state (e.g., “0”). Furthermore, the signal FBB is an inverted version of the signal FB with the delay of inverter 1083. When the duty cycle of the signal X1 is not 50%, it indicates that the logic states of the signals FB and FBB could be the same in a time period within one clock cycle. The LPFs 1102 and 1101 may convert the duty cycle of the signals FB and FBB into the filtered signals FB_LPF and FBB_LPF that are provided to the input terminals of the operational amplifier 1103.

In some embodiments, the comparison stage 110 may form a negative feedback path. When there is difference between the filtered signals FB_LPF and FBB_LPF, the control signal Vctrl generated by the operational amplifier 1103 may be a positive value or a negative value, thereby increasing or decreasing the delay of the clock signal CKD generated by the voltage control stage 106. Thus, the delay of the differential clock signals IN2 and IN2B can be increased or decreased correspondingly. Additionally, the loop filter 1104 may be configured to stabilize the control signal Vctrl generated by the operational amplifier 1103, such as lowering variations of the control signal Vctrl. The operational amplifier 1103 performs the comparison operation between the filtered signal FB_LPB and FBB_LPF repeatedly until the operational amplifier 1103 reaches a balance state or a “lock” state, indicating that the filtered signals FB_LPF and FBB_LPF are substantially equal, i.e., no difference exists between filtered signals FB_LPF and FBB_LPF or the difference therebetween is not significant enough to trigger the operational amplifier 1103. In other words, when the operational amplifier 1103 reaches the lock state, it indicates that the signal X1 generated by the logic gate 1081 and the output clock signal CKO have a duty cycle substantially equal to 50% and a frequency equal to that of the input clock signal CKI.

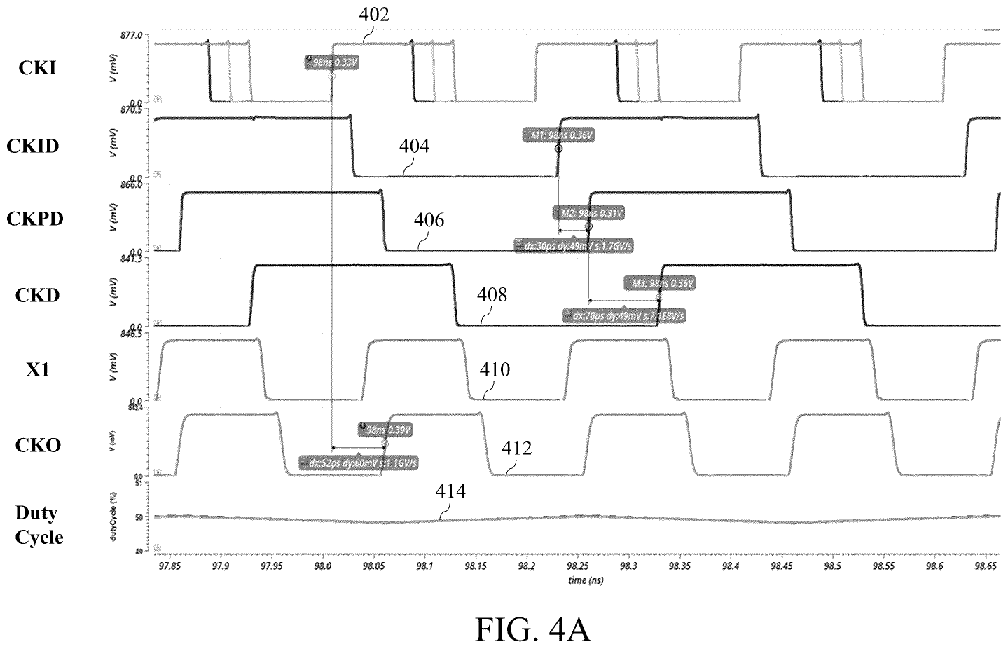

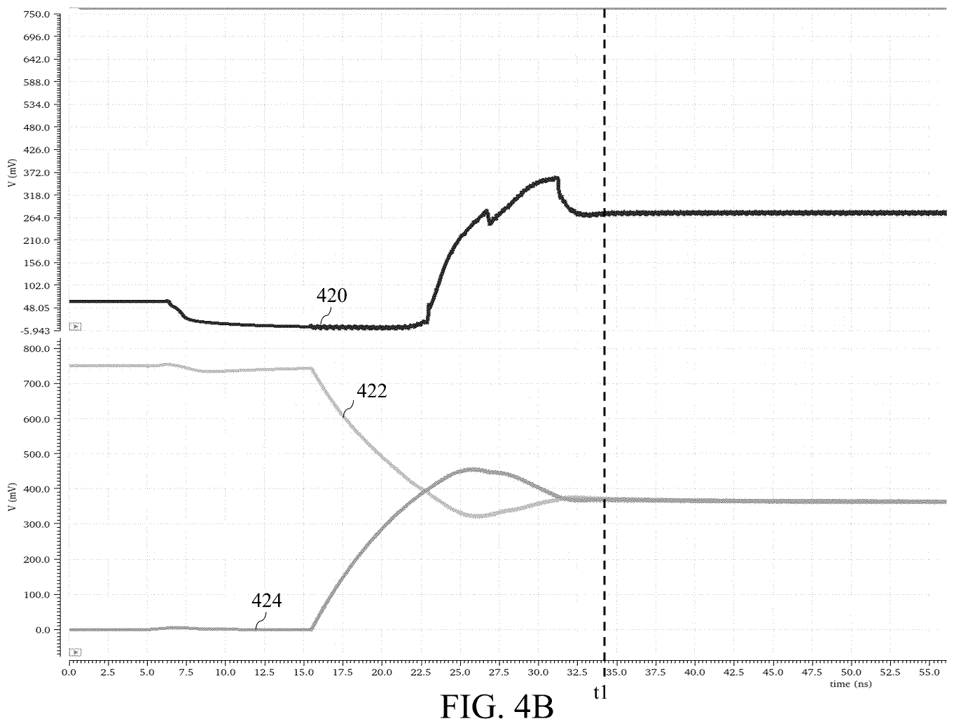

FIG. 4A is a waveform diagram of various clock signals within the duty-cycle corrector circuit 100A in FIG. 3. FIG. 4B is a waveform diagram of input and output signals of the operational amplifier in FIG. 3.

In some embodiments, the duty cycle of the input clock signal CKI may be between 40% and 60%, as shown by curve 402 in FIG. 4A. After the divider stage 102, the clock signal CKID (e.g., CKI/2) may have half frequency of the input clock signal CKI with a duty cycle approximately equal to 50% despite of the duty cycle (e.g., between 40% and 60%) of the input signal CKI, as shown by curve 404 in FIG. 4A. The frequency trimming stage 104 may delay the clock signal CKID, based on the associated register value, to generate the clock signal CKPD, as shown by curve 406 in FIG. 4A. As depicted in FIG. 4, the clock signal CKPD has a 30 ps delay after the clock signal CKID. Furthermore, when the operational amplifier 1103 enters the lock state or balance state at time t1 shown in FIG. 4B, the voltage control stage 106 may add a 70 ps delay to the clock signal CKPD to generate the clock signal CKD, as shown by curve 408 in FIG. 4A, according to the control signal Vctrl generated by the comparison stage 110. For example, the filtered signals FB_LPF and FBB_LPF, as shown by curves 422 and 424 in FIG. 4B, may be substantially equal after time t1. Accordingly, the signal X1 and the output clock signal CKO, as shown by curves 410 and 412 in FIG. 4A, may have a duty cycle substantially equal to 50% as shown by curve 414 in FIG. 4A.

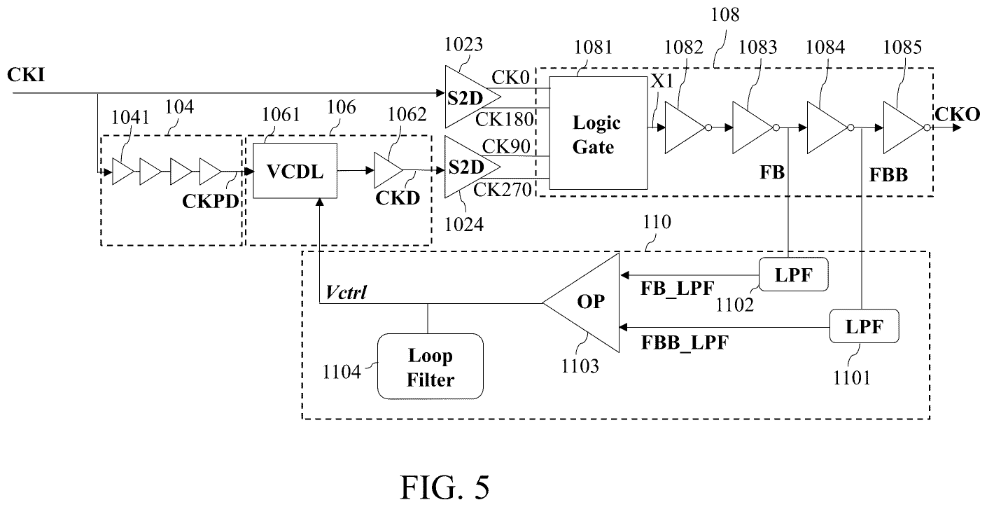

FIG. 5 is a block diagram of a frequency multiplier circuit in accordance with some embodiments of the present disclosure.

In some embodiments, the frequency multiplier circuit 100B shown in FIG. 5 may be similar to the duty-cycle corrector circuit 100A shown in FIG. 3, with the difference being that the divider stage 102 is omitted from the frequency multiplier circuit 100B. For example, the input clock signal CKI shown in FIG. 5 may have a duty cycle of 50% and a phase of 0 degree. Since the divider stage 102 does not exist, the input clock signal CKI rather than the divided clock signal CKID is provided to the frequency trimming stage 104 and the S2D circuit 1023 in FIG. 5. Thus, the output clock signal CKO may have twice frequency of the input clock signal CKI. In some embodiments, the differential clock signals CK0 and CK180, which have a phase of 0 and 180 degrees, are generated by the S2D circuit 1023, while the differential clock signals CK90 and CK270, which have phases of 90 and 270 degrees, are generated by the S2D circuit 1024. It should be noted that since the phase difference between the clock signals CK0 and CK180 is 180 degrees, the clock signal CK180 is complementary to the clock signal CK0. Similarly, the clock signal CK270 is complementary to the clock signal CK90. Accordingly, the output clock signal CKO generated by the logic stage 108 can have twice frequency of the input clock signal.

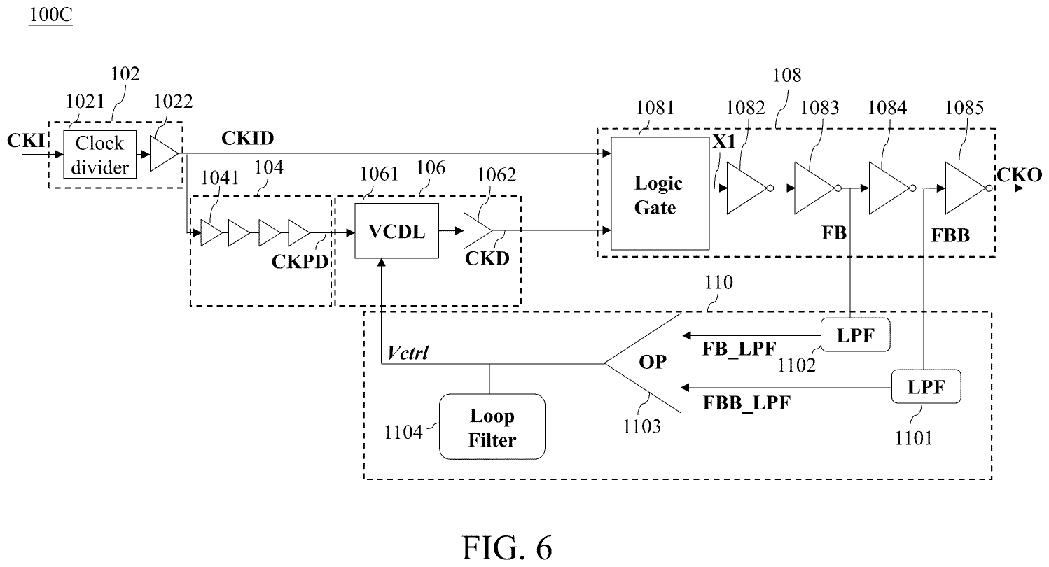

FIG. 6 is a block diagram of a duty-cycle corrector circuit in accordance with some embodiments of the present disclosure.

In some embodiments, the duty-cycle corrector circuit 100C shown in FIG. 6 may be similar to the duty-cycle corrector circuit 100A shown in FIG. 3, with the difference being that the S2D circuits 1023 and 1024 are omitted from the duty-cycle corrector circuit 100C. In other words, the clock signals CKID and CKD serves as two input signals for the logic gate 1081. Since the logic gate 1081 is an XOR gate or an XNOR gate implemented using CMOS logic, the logic gate 1081 includes two inverters therein to convert the clock signals CKID and CKD to their complementary signals CKIDB and CKDB. Accordingly, the clock signals CKID, CKIDB, CKD, and CKDB can be provided to respective transistors (not shown) within the logic gate 1081 to generate the signal X1.

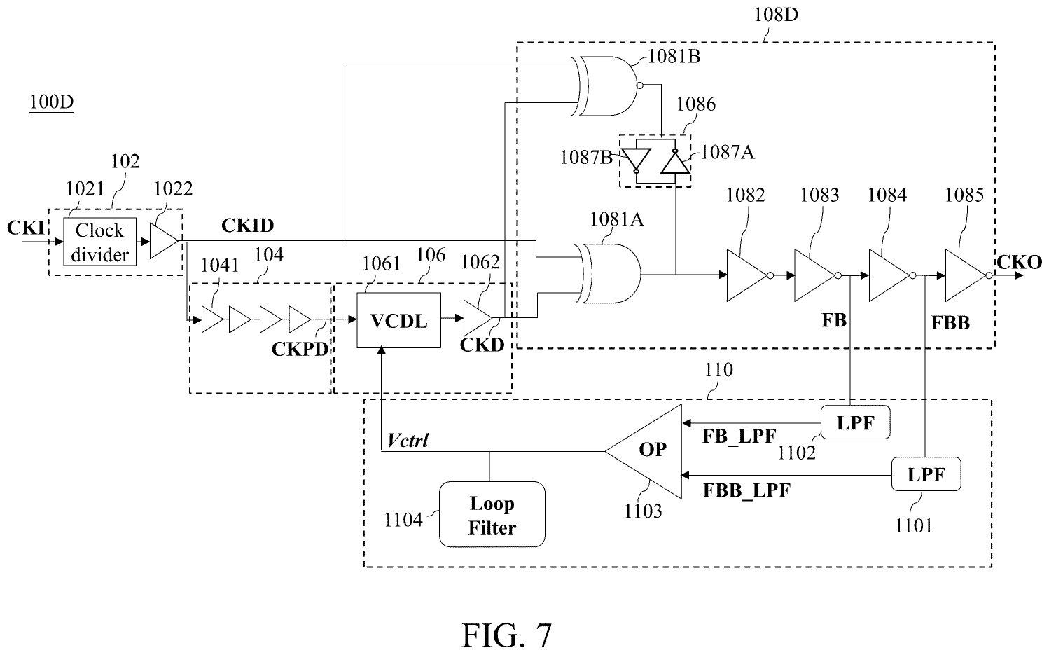

FIG. 7 is a block diagram of a duty-cycle corrector circuit in accordance with some embodiments of the present disclosure.

In some embodiments, the duty-cycle corrector circuit 100D shown in FIG. 7 is similar to the duty-cycle corrector circuit 100A shown in FIG. 6, with the difference being that the logic gate 1081 is implemented using an XOR gate 1081A, an XNOR gate 1081B, and a cross-coupled inverter stage 1086 within the logic stage 108D of the duty-cycle corrector circuit 100D. For example, both the clock signals CKID and CKD are provided to the XOR gate 1081A and the XNOR gate 1081B. Additionally, the cross-coupled inverter stage 1086, which includes inverters 1087A and 1087B, is coupled between the output terminals of the XOR gate 1081A and the XNOR gate 1081B, thereby reducing the random jitter (Rj) and deterministic jitter (Dj) of the output clock signal CKO. Specifically, the XOR gate 1081A is capable of detecting the condition that the logic states of the clock signals CKID and CKD are different (e.g., CKID=1 and CKD=0, or CKID=0, and CKD=1), while the XNOR gate 1081B is capable of detecting the condition that the logic states of the clock signals CKID and CKD are the same (e.g., CKID=CKD=0, or CKID=CKD=1). Additionally, the output clock signal CKO generated by the logic stage 108A has a duty cycle substantially equal to 50%. It should be noted that since the duty-cycle corrector circuit 100D does not include the S2D circuits 1023 and 1024, the logic stage 108A may further includes two inverters (not shown) to convert the clock signals CKID and CKD to their complementary clock signals CKIDB and CKDB (not shown).

In some other embodiments, the S2D circuits 1023 and 1024 can be disposed within the duty-cycle corrector circuit 100D to convert the clock signals CKID and CKD into respective differential clock signals, such as clock signals IN1, IN1B, IN2, and IN2 shown in FIG. 3, in a manner similar to the duty-cycle corrector circuit 100A in FIG. 3, thereby improving the accuracy of the output clock signal CK0.

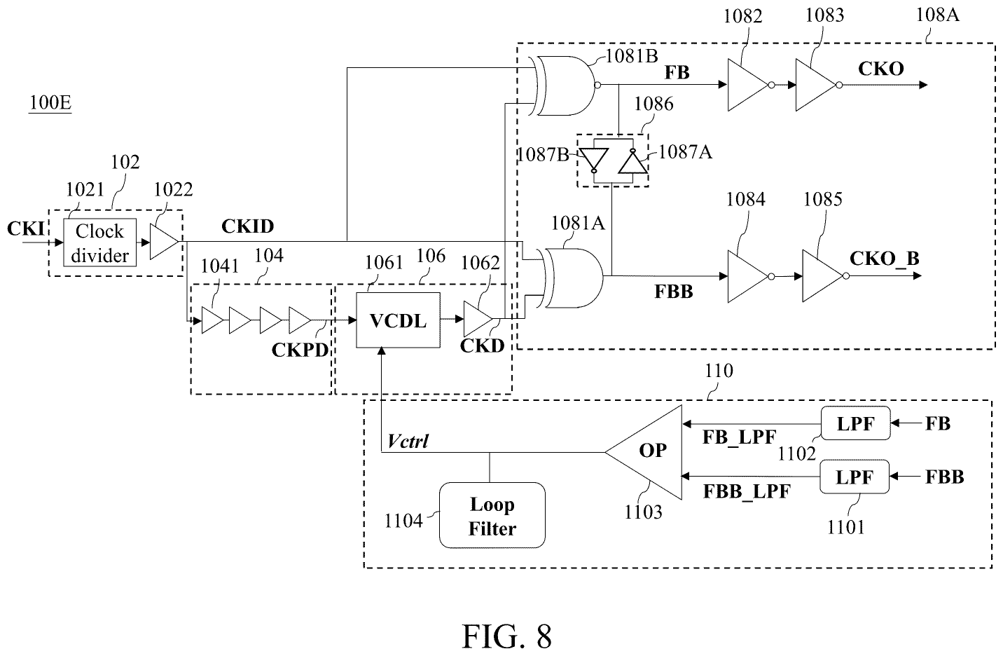

FIG. 8 is a block diagram of a duty-cycle corrector circuit in accordance with some embodiments of the present disclosure.

In some embodiments, the duty-cycle corrector circuit 100E shown in FIG. 8 may be similar to the duty-cycle corrector circuit 100D shown in FIG. 7, with the different being that an inverter chain, which includes the inverters 1082 and 1083, is connected to the output terminal of the XNOR gate 1081B within the logic stage 108A, while another inverter chain, which includes the inverters 1084 and 1085, is connected to the output terminal of the XOR gate 1081A within the logic stage 108A. Additionally, the output signals of the XOR gate 1081A and XNOR gate 1081B may be used as the signals FBB and FB that are provided to the LPFs 1101 and 1102, as shown in FIG. 8. It should be noted that the output signals of the XOR gate 1081A and XNOR gate 1081B, i.e., signals FBB and FB, may be substantially complementary to each other with a duty cycle of 50% when the operational amplifier 1103 enters the lock state. Since there are two inverter stages at the output terminals of the XOR gate 1081A and XNOR gate 1081B, the delay of generating the output clock signals CKO and CKO_B can be reduced.

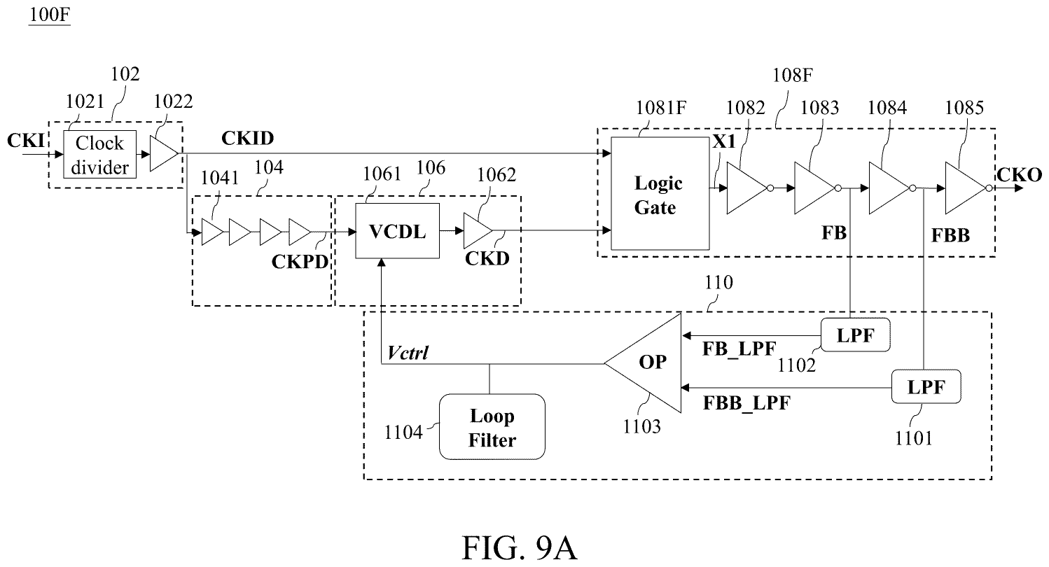

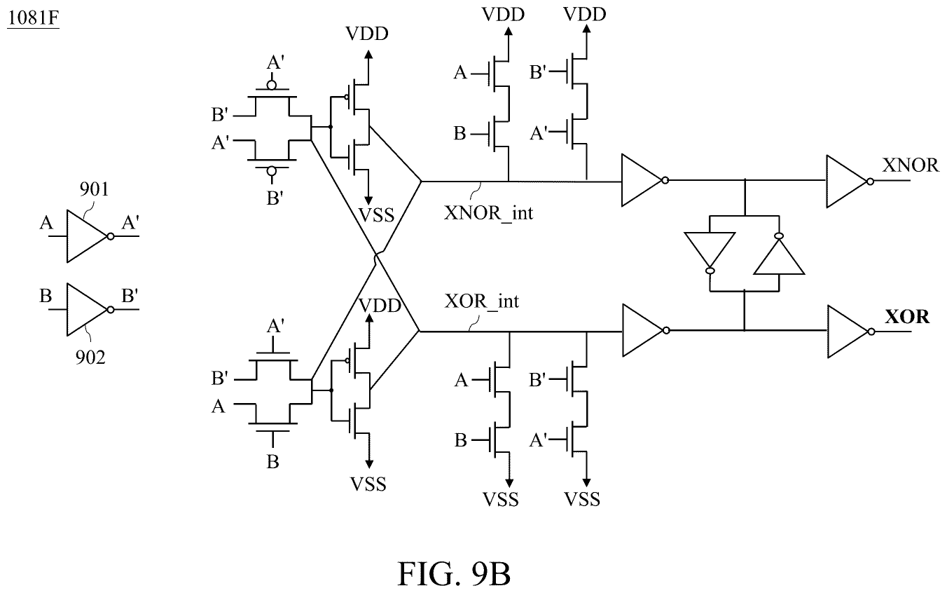

FIG. 9A is a block diagram of a duty-cycle corrector circuit in accordance with some embodiments of the present disclosure. FIG. 9B is a schematic diagram of the logic gate in FIG. 9A.

In some embodiments, the duty-cycle corrector circuit 100F shown in FIG. 9A may be similar to the duty-cycle corrector circuit 100C shown in FIG. 6, with the different being that the logic gate 1081F within the logic stage 108F in FIG. 9A is implemented using a composite circuit with the XOR-XNOR function, as shown in FIG. 9B. For example, the input signals A and B, which refer to the clock signals CKID and CKD, are converted by respective inverters to generate the signals A′ and B′. The signals A′ and B′ are provided to respective transistors to generate intermediate signals XOR_int and XNOR_int. The intermediate signals XOR_int and XNOR_int passes through respective inverter chains to generate the output XOR and XNOR signals, as shown in FIG. 9B. It should be noted that the logic gate 1081F is a composite XOR-XNOR gate, where the XOR portion includes the lower half circuit, while the XNOR portion includes the upper half circuit. Furthermore, one of the output XOR and XNOR signals can be used within the logic stage 108F.

In some embodiments, the XOR gate 1081A and XNOR gate 1081B shown in FIG. 8 can be implemented using the composite XOR-XNOR gate 1081F shown in FIG. 9B.

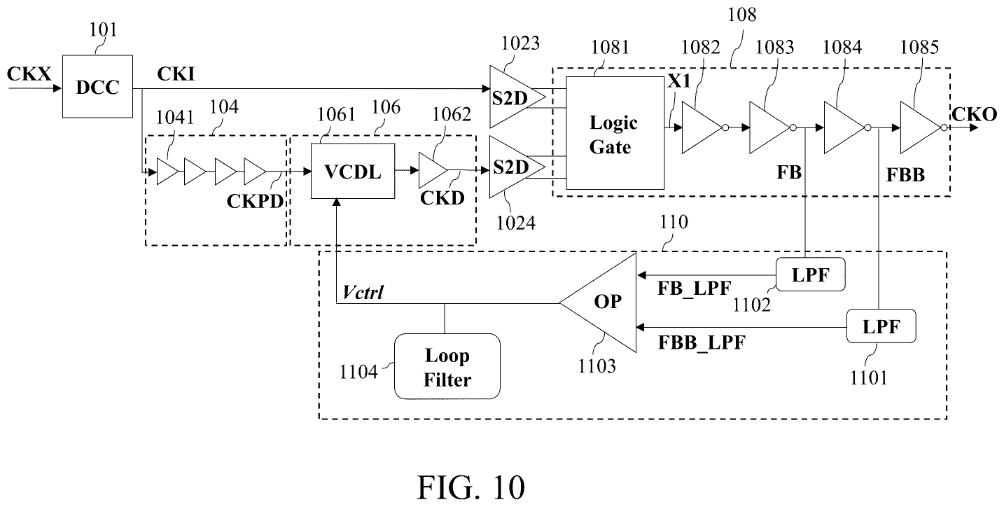

FIG. 10 is a block diagram of a frequency multiplier circuit in accordance with some embodiments of the present disclosure.

In some embodiments, the frequency multiplier circuit 100G shown in FIG. 10 may be similar to the frequency multiplier circuit 100B shown in FIG. 5, with the difference being that an additional duty-cycle corrector circuit 101 is disposed within the frequency multiplier circuit 100G to correct the duty cycle of a clock signal CKX to generate the input clock signal CKI, wherein the clock signal CKX has the duty cycle substantially equal to 50%. More specifically, the architecture of the duty-cycle corrector circuit 100A shown FIG. 3 can implement the function of a frequency multiplier by removing the divider stage 102, as shown by the frequency multiplier circuit 100B shown in FIG. 5. However, the input clock signal CKI should have a duty cycle of approximately 50% to guarantee the frequency multiplier function. Accordingly, an additional duty-cycle corrector circuit 101 is added to the input terminal of the frequency multiplier circuit 100B to ensure that the input clock signal CKI, which is converted from the clock signal CKX, have a duty cycle of 50%, as shown by the frequency multiplier circuit 100G shown in FIG. 10.

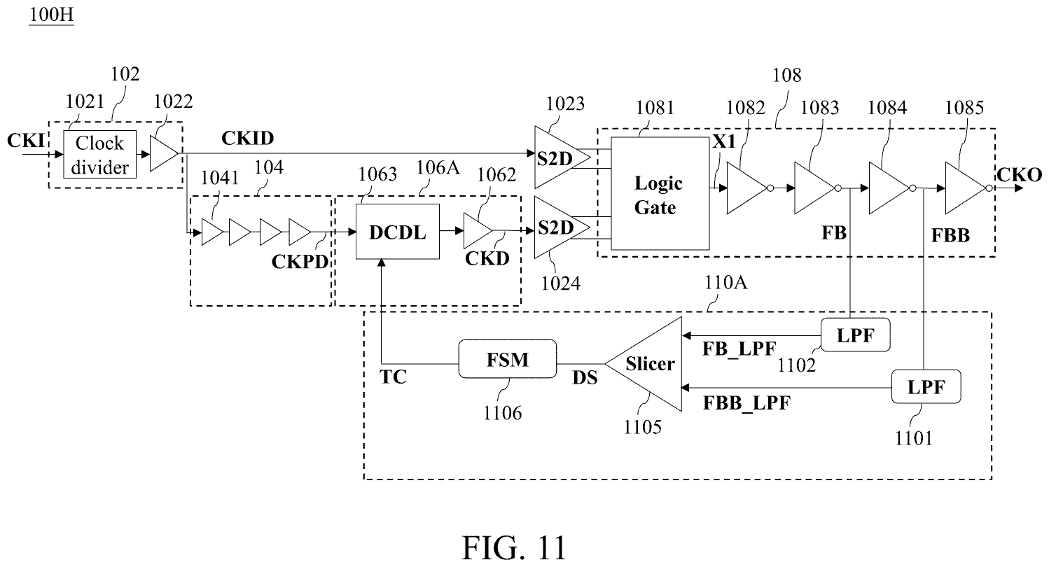

FIG. 11 is a block diagram of a duty-cycle corrector circuit in accordance with some embodiments of the present disclosure.

In some embodiments, the duty-cycle corrector circuit 100H shown in FIG. 11 may be similar to the duty-cycle corrector circuit 100A shown in FIG. 3, with the difference being that digital circuit designs are applied to the voltage control stage 106A and the comparison stage 110H within the duty-cycle corrector circuit 100H shown in FIG. 11, while the voltage control stage 106 and the comparison stage 110 within the duty-cycle corrector circuit 100A shown in FIG. 3 utilize the analog approaches for the signal feedback path and voltage controlled delay line. Specifically, the comparison stage 110A may employ a slicer 1105 and a finite state machine (FSM) 1106 which are digital circuits. The slicer 1105 can be regarded as a data slicer that is configured to receive the filtered signals FB_LPF and FBB_LPF generated by the LPFs 1102 and 1101, and convert the difference between the filtered signals FB_LPF and FBB_LPF into a digital signal DS indicating a voltage level. The digital signal DS is transmitted to the finite state machine 1106, enabling the finite state machine 1106 to switch to an appropriate state among a plurality of states to output a corresponding trimming code TC (e.g., a digital signal).

In some embodiments, the voltage control stage 106 includes a digitally-controlled delay line (DCDL) 1063 and the buffer 1062. The DCDL 1063 may be configured to adjust the delay of the clock signal CKPD based on the trimming code TC generated by the finite state machine 1106. Specifically, the delay of the clock signal CKD, which is buffered by the buffer 1062, generated by the DCDL 1063 can be adjusted by the voltage applied to the DCDL 1063 which is controlled the trimming code TC generated by the finite state machine 1106 within the comparison stage 110. Additionally, the delay of the clock signal CKD can be either a positive value or a negative value. It should be noted that the function of the voltage control stage 106A shown in FIG. 11 is similar to the voltage control stage 106 shown in FIG. 3. The mechanism for adjusting the delay of the clock signal CKD performed by the DCDL 1063 within the duty-cycle corrector circuit 100H may be similar to that performed by the VCDL 1061 within the duty-cycle corrector circuit 100A shown in FIG. 3, and thus the details thereof are not repeated here.

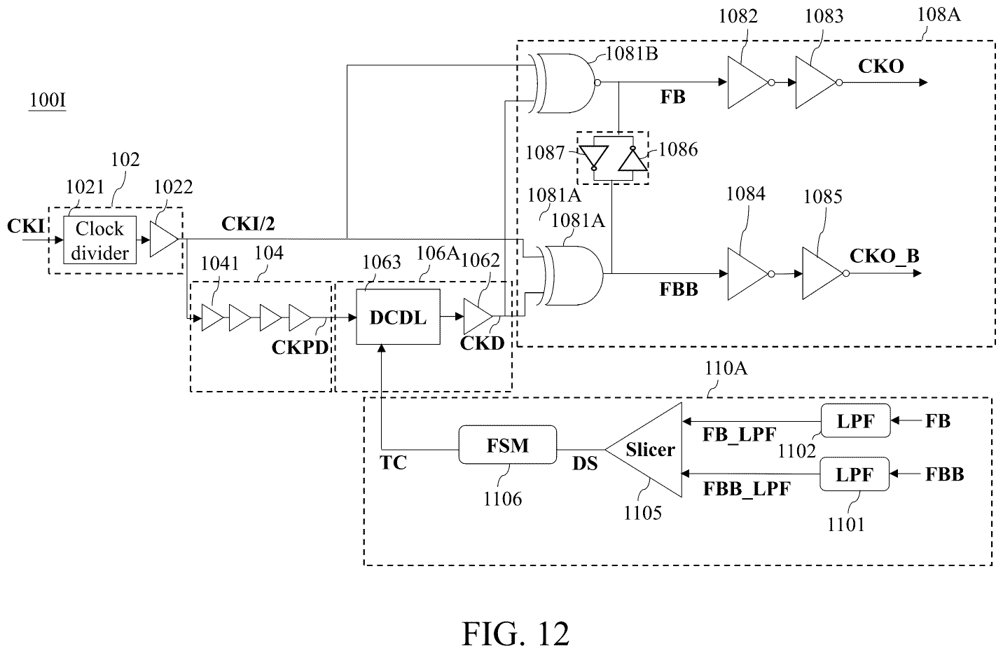

FIG. 12 is a block diagram of a duty-cycle corrector circuit in accordance with some embodiments of the present disclosure.

In some embodiments, the duty-cycle corrector circuit 100I shown in FIG. 12 may be similar to the duty-cycle corrector circuit 100E shown in FIG. 8, with the difference being that the digital circuit designs are applied to the voltage control stage 1061 and the comparison stage 110I within the duty-cycle corrector circuit 100I shown in FIG. 12, while the voltage control stage 106 and the comparison stage 110 within the duty-cycle corrector circuit 100E shown in FIG. 8 utilize the analog approaches for the signal feedback path and voltage controlled delay line. Specifically, the comparison stage 110A may employ a slicer 1105 and a finite state machine (FSM) 1106 which are digital circuits. The slicer 1105 can be regarded as a data slicer that is configured to receive the filtered signals FB_LPF and FBB_LPF generated by the LPFs 1102 and 1101, and convert the difference between the filtered signals FB_LPF and FBB_LPF into a digital signal DS indicating a voltage level. The digital signal DS is transmitted to the finite state machine 1106, enabling the finite state machine 1106 to switch to an appropriate state among a plurality of states to output a corresponding trimming code TC (e.g., a digital signal). As described in the embodiments of FIG. 11, the delay of the clock signal CKD, which is buffered by the buffer 1062, generated by the DCDL 1063 can be adjusted by the voltage applied to the DCDL 1063 which is controlled the trimming code TC generated by the finite state machine 1106 within the comparison stage 110. Additionally, the delay of the clock signal CKD can be either a positive value or a negative value.

In some embodiments, the logic stage 108A is in a differential output structure. Since the output terminals of the XOR gate 1081A and XNOR gate 1081B are connected to respective inverter chains, each with two stages of inverters such as inverters 1084-1085 and 1082-1083, the delays of the output clock signals CKO and CKO_B can be reduced.

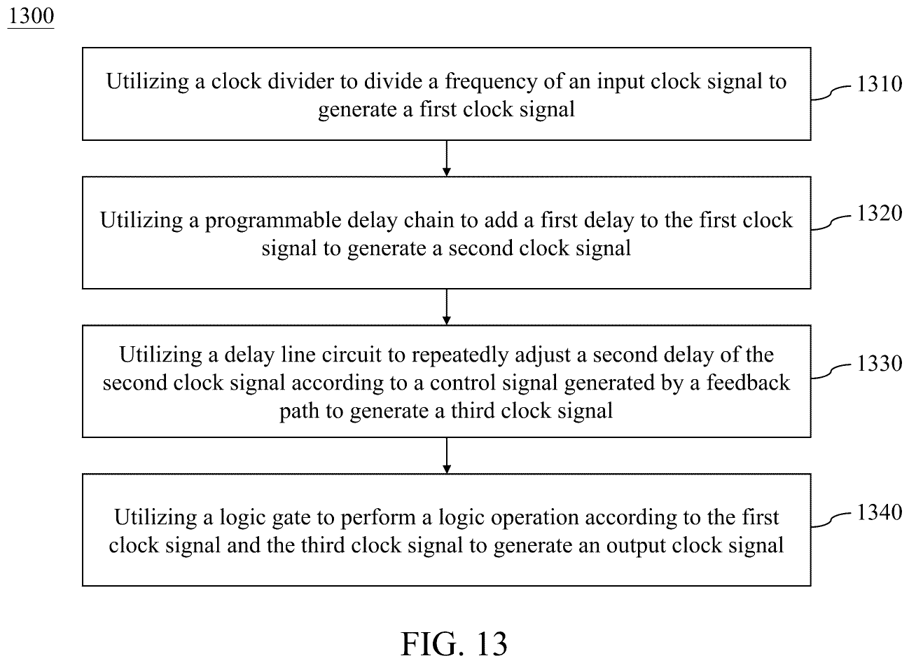

FIG. 13 is a flowchart of a method for operating a duty-cycle corrector circuit in accordance with some embodiments of the present disclosure. Please refer to both FIG. 2 and FIG. 13. The flow 1300 includes operations 1310 to 1340. It should be noted that the flow 1300 can include additional operations.

At operation 1310, a clock divider is utilized to generate a first clock signal by dividing a frequency of an input clock signal. For example, the clock divider 1021 may divide the frequency of the input clock signal CKI by 2 to obtain the first clock signal CKID. Additionally, the first clock signal CKID may have a duty cycle of 50% and half frequency of the input clock signal CKI.

At operation 1320, a programmable delay chain is utilized to add a first delay to the first clock signal to generate a second clock signal. For example, the frequency trimming stage 104 includes a plurality of delay elements, such as buffers 1041. Additionally, the first delay is programmable via a corresponding register value.

At operation 1330, a delay line circuit is utilized to repeatedly adjust a second delay of the second clock signal to generate a third clock signal according to a control signal generated by a feedback path. For example, the delay line circuit can be the VCDL 1061 or DCDL 1063 as described above. The VCDL 1061 may use an analog approach to adjust the voltage for adjusting the second delay according to the voltage control signal Vctrl, while the DCDL 1063 may use a digital approach to adjust the voltage for adjusting the second delay according to the trimming code TC.

At operation 1340, a logic stage is utilized to generate an output clock signal according to the first clock signal and the third clock signal. For example, the logic stage 108 may include an XOR or XNOR gate (e.g., XOR gate 1081), or both XOR and XNOR gates (e.g., XOR gate 1081A and XNOR gate 1081B). Additionally, the XOR gate 1081A and XNOR gate 1081B can be separate logic gates, or a composite XOR-XNOR gate, as shown by the composite XOR-XNOR gate 1081F shown in FIG. 9B.

An aspect of the present disclosure provides an integrated circuit, which includes a divider stage, a frequency trimming stage, a voltage control stage, and a logic stage. The divider stage is configured to generate a first clock signal by dividing a frequency of an input clock signal. The frequency trimming stage is configured to add a first delay to the first clock signal to generate a second clock signal. The voltage control stage is configured to repeatedly adjust a second delay of the second clock signal according to a control signal generated by a feedback path to generate a third clock signal. The logic stage is configured to perform a logic operation according to the first clock signal and the third clock signal to generate an output clock signal. Another aspect of the present disclosure provides an integrated circuit, which includes a divider stage, a frequency trimming stage, a voltage control stage, a first single-to-differential circuit, a second single-to-differential circuit, and a logic stage. The divider stage is configured to divide a frequency of an input clock signal to generate a first clock signal. The frequency trimming stage is configured to add a first delay to the first clock signal to generate a second clock signal. The voltage control stage is configured to repeatedly adjust a second delay of the second clock signal according to a control signal generated by a feedback path to generate a third clock signal. The first single-to-differential circuit is configured to convert the first clock signal into first differential clock signals. The second single-to-differential circuit is configured to convert the third clock signal into second differential clock signals. The logic stage is configured to perform a logic operation using the first differential clock signals and the second differential clock signals to generate a first output clock signal.

Yet another aspect of the present disclosure provides a method, which includes the following steps: utilizing a clock divider to divide a frequency of an input clock signal to generate a first clock signal; utilizing a programmable delay chain to add a first delay to the first clock signal to generate a second clock signal; utilizing a voltage-controlled delay line to repeatedly adjust a second delay of the second clock signal according to a control signal generated by a feedback path to generate a third clock signal; and utilizing a logic gate to perform a logic operation according to the first clock signal and the third clock signal to generate an output clock signal.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. An integrated circuit, comprising:
a divider stage, configured to generate a first clock signal by dividing a frequency of an input clock signal;
a frequency trimming stage, configured to add a first delay to the first clock signal to generate a second clock signal;
a voltage control stage, configured to repeatedly adjust a second delay of the second clock signal according to a control signal generated by a feedback path to generate a third clock signal; and
a logic stage, configured to perform a logic operation according to the first clock signal and the third clock signal to generate an output clock signal.

2. The integrated circuit of claim 1, wherein the divider stage comprises:
a clock divider, configured to divide the frequency of the input clock signal by 2 to generate the first clock signal; and
a first buffer, configured to buffer the first clock signal.

3. The integrated circuit of claim 1, wherein the frequency trimming stage comprises a plurality of delay elements.

4. The integrated circuit of claim 3, wherein the delay elements are inverters or buffers.

5. The integrated circuit of claim 3, wherein the first delay added to the first clock signal through the delay elements is programmable via a register value.

6. The integrated circuit of claim 1, wherein the voltage control stage comprises:
a delay line, configured to adjust the second delay of the second clock signal according to the control signal; and
a second buffer, configured to buffer the second clock signal.

7. The integrated circuit of claim 6, wherein the logic stage comprises:
a logic gate, configured to perform the logic operation according to the first clock signal and the third clock signal to generate the output clock signal; and
an inverter chain, configured to buffer the output clock signal.

8. The integrated circuit of claim 7, wherein the feedback path comprises:
a first low-pass filter and a second low-pass filter configured to filter a first signal and a second signal obtained from a first point and a second point within the inverter chain to generate a first filtered signal and a second filtered signal, respectively; and
a comparison circuit, configured to compare the first filtered signal and the second filtered signal to generate the control signal.

9. The integrated circuit of claim 8, wherein the comparison circuit comprises an operational amplifier and a loop filter configured to stabilize a voltage control signal generated by the operational amplifier, and the voltage control signal is used as the control signal.

10. The integrated circuit of claim 9, wherein the delay line comprises a voltage-controlled delay line controlled by the voltage control signal to adjust the second delay of the second clock signal to generate the third clock signal.

11. The integrated circuit of claim 8, wherein the comparison circuit comprises:
a data slicer, configured to compare the first filtered signal and the second filtered signal to generate a digital signal; and
a finite state machine, configured to switch to a state corresponding to the digital signal to generate a respective trimming code, wherein the respective trimming code is used as the control signal.

12. The integrated circuit of claim 11, wherein the delay line comprises a digitally-controlled delay line controlled by the respective trimming code to adjust the second delay of the second clock signal to generate the third clock signal.

13. The integrated circuit of claim 11, further comprising:
a first single-to-differential circuit, configured to convert the first clock signal into first differential clock signals; and
a second single-to-differential circuit, configured to convert the third clock signal into second differential clock signals,
wherein the logic stage is configured to perform the logic operation using the first differential clock signals and the second differential clock signals to generate the output clock signal.

14. An integrated circuit, comprising:
a divider stage, configured to divide a frequency of an input clock signal (CKI) and generate a first clock signal;
a frequency trimming stage, configured to add a first delay to the first clock signal to generate a second clock signal;
a voltage control stage, configured to repeatedly adjust a second delay of the second clock signal according to a control signal generated by a feedback path to generate a third clock signal;
a first single-to-differential circuit, configured to convert the first clock signal into first differential clock signals;
a second single-to-differential circuit, configured to convert the third clock signal into second differential clock signals; and
a logic stage, configured to perform a logic operation using the first differential clock signals and the second differential clock signals to generate a first output clock signal.

15. The integrated circuit of claim 14, wherein the logic stage comprises:
an XNOR gate, configured to perform an XNOR operation using the first differential clock signals and the second differential clock signals to generate a first intermediate clock signal;
an XOR gate, configured to perform an XOR operation using the first differential clock signals and the second differential clock signals to generate a second intermediate clock signal;
two cross-coupled inverters, coupled between a first output terminal of the XNOR gate and a second output terminal of the XOR gate;
a first inverter chain, connected to the first output terminal of the XNOR gate, and configured to delay the first intermediate clock signal to generate the first output clock signal; and
a second inverter chain, connected to the second output terminal of the XOR gate, and configured to delay the second intermediate clock signal to generate a second output clock which is complementary to the first output clock signal.

16. The integrated circuit of claim 15, wherein the XOR gate and the XNOR gate are implemented using a composite XOR-XNOR gate.

17. The integrated circuit of claim 14, wherein the feedback path is an analog feedback path configured to generate an analog voltage control signal as the control signal, and the voltage control stage comprises a voltage-controlled delay line to adjust the second delay of the second clock signal to generate the third clock signal according to the control signal.

18. The integrated circuit of claim 14, wherein the feedback path is a digital feedback path configured to generate a trimming code as the control signal, and the voltage control stage comprises a digitally-controlled delay line to adjust the second delay of the second clock signal to generate the third clock signal according to the trimming code.

19. A method, comprising:
utilizing a clock divider to divide a frequency an input clock signal to generate a first clock signal;
utilizing a programmable delay chain to add a first delay to the first clock signal to generate a second clock signal;
utilizing a delay line circuit to repeatedly adjust a second delay of the second clock signal according to a control signal generated by a feedback path to generate a third clock signal; and
utilizing a logic gate to perform a logic operation according to the first clock signal and the third clock signal to generate an output clock signal.

20. The method of claim 19, the step of utilizing the logic gate to perform the logic operation according to the first clock signal and the third clock signal to generate the output clock signal comprises:
utilizing a first single-to-differential circuit and a second single-to-differential circuit to convert the first clock signal and the third clock signal into a first differential clock signal pair and a second differential clock signal pair, respectively; and
utilizing the logic gate to perform an XOR operation or an XNOR operation using the first differential clock signal pair and the second differential clock signal pair to generate the output clock signal.
